(19) United States
(12) Patent Application Publication
(10) Pub. No.: US 2014/0036598 A1
(43) Pub. Date: Feb. 6, 2014

(54) SEMICONDUCTOR MEMORY DEVICE AND OPERATING METHOD THEREOF

(71) Applicant: Hea Jong YANG, Seoul (KR)

(72) Inventor: Hea Jong YANG, Seoul (KR)

(73) Assignee: SK HYNIX INC., Icheon-si (KR)

(21) Appl. No.: 13/602,107

(22) Filed: Sep. 1, 2012

(30) Foreign Application Priority Data
Jul. 31, 2012 (KR) 10-2012-0083835

(51) Int. Cl. G11C 16/06

(52) U.S. Cl. 365/185.22

(57) ABSTRACT

A semiconductor memory device and a method of operating the same are disclosed. The semiconductor memory device includes a select transistor, memory cells connected in serial and dummy memory cells disposed between the select transistor and the memory cells. A higher voltage is applied to a corresponding dummy memory cell as space between the corresponding dummy memory cell and the select to transistor is reduced in an erase operation.

### CROSS-REFERENCE TO RELATED APPLICATION

This application claims priority from Korean

Patent Application No. 10-2012-0083835, filed on Jul. 31, 2012, the contents of which are incorporated herein by reference in its entirety.

### BACKGROUND

The present invention relates generally to a semiconductor memory device and an operating method thereof.

A semiconductor memory is a memory device formed by using materials such as silicon Si, Germanium Ge, gallium arsenide GaAs, and indium phospide InP. The semiconductor memory is typically divided into volatile and non-volatile categories.

In volatile memory devices, data is erased when a power source is removed. Such devices include static RAM SRAM, a dynamic RAM DRAM, a synchronous DRAM SDRAM, etc. In non-volatile memory devices, data is maintained even when a power source is removed. Such devices include a read only memory ROM, a programmable ROM PROM, an electrically programmable ROM EPROM, an electrically erasable and programmable ROM EEPROM, a flash memory, a phase-change RAM PRAM, a magnetic RAM MRAM, a resistive RAM RRAM, a ferroelectric RAM FRAM, etc. The flash memory is typically divided into a NOR type and a NAND type.

Dummy memory cells may be used in a memory cell array of a semiconductor memory device to aid normal operation, such as reducing interference when various operations of the semiconductor memory device are performed.

### SUMMARY OF THE INVENTION

Various embodiments of the present invention provide a semiconductor memory device with enhanced reliability by reducing a deterioration phenomenon within the memory cell array.

A semiconductor memory device according to an embodiment of the present invention includes a select transistor; memory cells connected in serial; and dummy memory cells disposed between the select transistor and the memory cells. A higher voltage is applied to a corresponding dummy memory cell as space between the corresponding dummy memory cell and the select transistor is reduced in an erase operation.

The voltage provided to a dummy memory cell adjacent to the select transistor is the same voltage applied to a select line connected to the select transistor. The select line connected to the select transistor and the dummy word line connected to a dummy memory cell adjacent to the select transistor are floating.

In an erase verifying operation following the erase operation, a higher level dummy verifying voltage is applied to corresponding dummy memory cells as space between the dummy memory cell and the select transistor is reduced.

A semiconductor memory device according to another embodiment of the present invention includes a memory cell array having a select transistor, memory cells connected in serial; dummy memory cells disposed between the select transistor and the memory cells; and a peripheral circuit configured to apply a higher level voltage to a corresponding dummy memory cell as space between the corresponding dummy memory cell and the select transistor is reduced in an erase operation.

The peripheral circuit is configured to have both a floating select line connected to the select transistor and a floating dummy word line connected to a dummy memory cell adjacent to the select transistor.

The peripheral circuit is configured to apply a higher level dummy verifying voltage to the corresponding dummy memory cell as space between the corresponding dummy memory cell and the select transistor is reduced in an erase verifying operation following the erase operation.

A method of operating a semiconductor memory device according to another embodiment of the present invention includes floating a select line connected to a select transistor in an erase operation; and applying a higher level voltage to each dummy memory cell disposed between the select transistor and memory cells as space between a corresponding dummy memory cell and the select transistor is reduced when the select line is floating.

The method further includes applying a higher level dummy word line voltage to corresponding dummy memory cells as space between the dummy memory cell and the select transistor is reduced in an erase verifying operation following the erase operation.

A voltage applied to a dummy memory cell adjacent to the select transistor has the same voltage level as a voltage applied to the select line.

A dummy word line connected to a dummy memory cell adjacent to the select transistor is floating.

Considering the above embodiments, it is possible for the reliability of a semiconductor memory device of the present invention to be enhanced.

### BRIEF DESCRIPTION OF THE DRAWINGS

The above and other features as well as advantages of the present invention will become readily apparent by reference to the following detailed description when considered in conjunction with the accompanying drawings wherein:

FIG. 1 is a block diagram illustrating a semiconductor memory device according to an embodiment of the present invention;

FIG. 2 is a view illustrating circuitry of one BLK1 of memory blocks BLK1˜BLKz in FIG. 1;

FIG. 3 is a view illustrating one CS1 of cell strings CS1˜CSm in FIG. 2;

FIG. 4 is a view illustrating a table showing voltages applied to row lines RL according to an embodiment of the present invention;

FIG. 5 is a timing diagram illustrating voltages of row lines RL according to the table in FIG. 4;

FIG. 6 is a view illustrating a table showing voltages applied to row lines RL according to an embodiment of the present invention;

FIG. 7 is a flowchart illustrating a method of erasing the contents of a semiconductor memory device in FIG. 1;

FIG. 8 is a view illustrating a table showing voltages applied to the row lines RL in an erase verifying operation; and

FIG. 9 is a view illustrating threshold voltage distribution of memory cells and dummy memory cells after the erase operation is performed.

### DESCRIPTION OF SPECIFIC EMBODIMENTS

Hereinafter, the preferred embodiments of the present invention will be explained in more detail with reference to the accompanying drawings. Although embodiments have been described with reference to a number of illustrative embodiments thereof, it should be understood that numerous other modifications and embodiments can be devised by those skilled in the art that will fall within the spirit and scope of the principles of this disclosure.

It should be understood that when an element is referred to as being “connected” or “coupled” to another element, it can be directly in indirectly connected or coupled to the other element. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

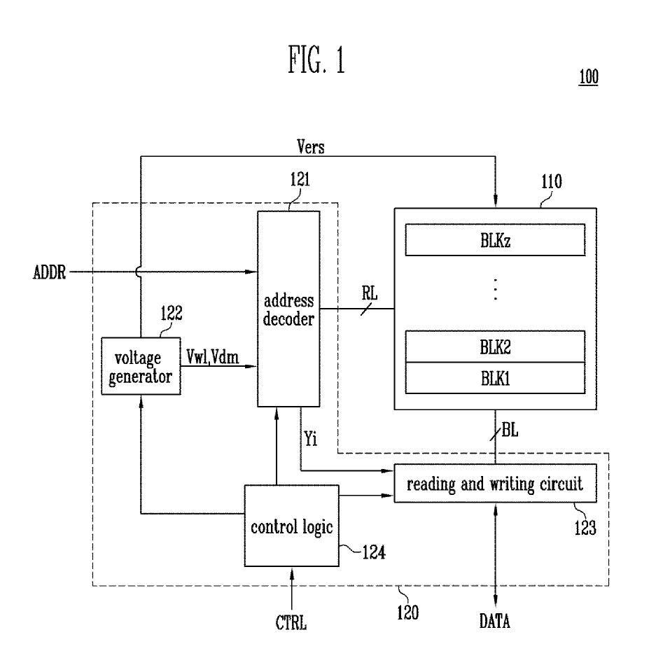

FIG. 1 is a block diagram illustrating a semiconductor memory device according to an embodiment of the present invention.

In FIG. 1, a semiconductor memory device 100 includes a memory cell array 110 and a peripheral circuit 120 to drive the memory cell array 110.

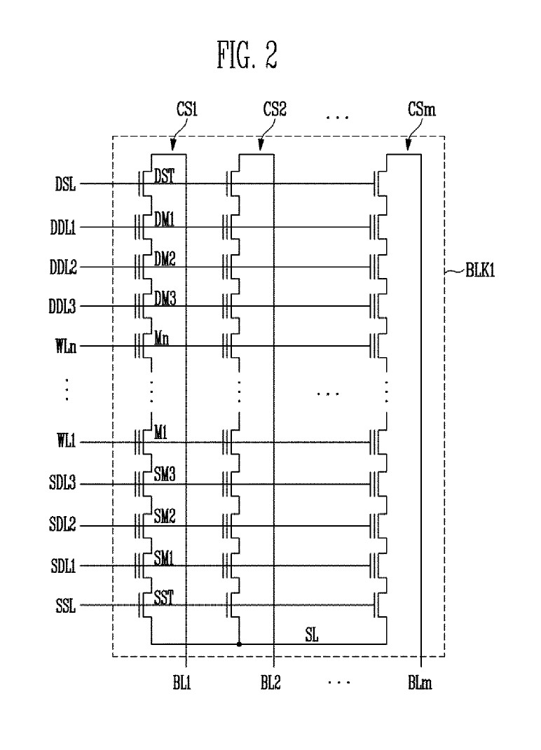

The memory cell array 110 is connected to an address decoder 121 through row lines RL, and to a reading and writing circuit 123 through bit lines BL. The row lines RL include a source select line, dummy word lines, word lines and a drain select line (as shown in FIG. 2). The memory cell array 110 has memory blocks BLK1˜BLKz, wherein each memory block includes non-volatile single or multi-level memory cells. Single-level memory cells are connected to one word line to form one page, and multi-level cells are connected to one word line to form two or more pages.

The peripheral circuit 120 includes the address decoder 121, a voltage generator 122, a reading and writing circuit 123 and a control logic 124.

The address decoder 121 is connected to the memory cell array 110 through the row lines RL and operates in response to control of the control logic 124. The address decoder 121 receives address ADDR from outside of the semiconductor memory device 100 or an input/output buffer (not shown) in the semiconductor memory device 100.

The address decoder 121 decodes a block address of the received address ADDR and selects one memory block according to the decoded block address.

Specifically, the address decoder 121 decodes the row address of the received address ADDR and selects one of the word lines according to the decoded row address.

The address decoder 121 also decodes the column address of the received address ADDR, and transmits the decoded column address Yi to the reading and writing circuit 123.

An erase operation of the semiconductor memory device is performed in a unit of a memory block, whereas a read operation and a program operation of the semiconductor memory device are performed in a unit of a page. In the erase operation, the address ADDR includes the block address, and the address decoder 121 selects one memory block according to the address ADDR. In the read operation and the program operation, the address ADDR includes the block address, the row address and the column address. The address decoder 121 selects one memory block and one word line according to the address ADDR, and provides the decoded column address Yi to the reading and writing circuit 123.

In an embodiment, the address decoder 121 may include a block decoder, a row decoder, a column decoder, an address buffer, etc.

The voltage generator 122 generates voltages using outside supply voltage provided to the semiconductor memory device 100 and operates in response to control of the control logic 124. The voltage generator 122 may regulate the supply voltage, or generate voltages by amplifying the supply voltage using a plurality of pumping capacitors.

In the erase operation, the voltage generator 122 generates a word line voltage Vw1 applied to the word lines, dummy word line voltage Vdm provided to dummy word lines, and an erase voltage Vers applied to a bulk area of the memory cell array 110.

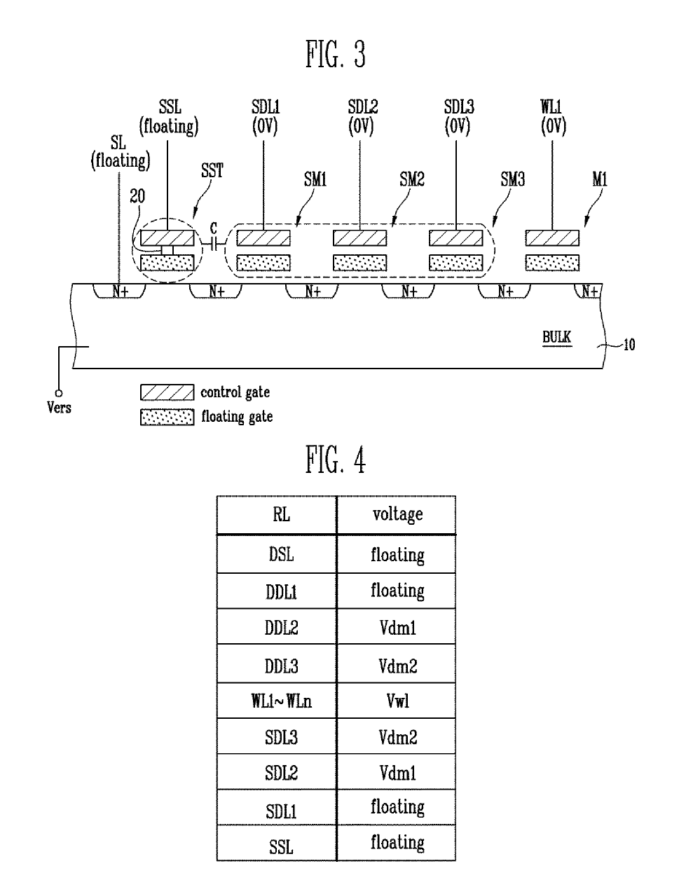

When the erase voltage Vers is generated from the voltage generator 122, the address decoder 121 may apply the word line voltage Vw1 to word lines connected to a selected memory block and to float word lines connected to unselected memory blocks. Additionally, the address decoder 121 may apply the dummy word line voltage Vdm to the dummy memory cells. This will be described in detail with reference to accompanying drawings FIG. 4 and FIG. 5.

The reading and writing circuit 123 is connected to the memory blocks BLK1˜BLKz through the bit lines BL, and operates in response to the control logic 124.

In a program operation and the read operation, the reading and writing circuit 123 exchanges data DATA with the outside or an input/output buffer (not shown) in the semiconductor memory device 100. In the program operation, the reading and writing circuit 123 receives the data DATA, and programs the received data DATA to memory cells of the selected word line. In the read operation, the reading and writing circuit 123 reads from the memory cells of the selected word line, and outputs data DATA corresponding to the decoded column address Yi of the read data.

The reading and writing circuit 123 may include page buffers (or page registers), a column select circuit and so on.

The control logic 124 is connected to the address decoder 121, the voltage generator 122 and the reading and writing circuit 123, and receives a control signal CTRL from the outside or the input/output buffer (not shown) in the semiconductor memory device 100. The control logic 124 controls operation of the semiconductor memory device 100 in response to the control signal CTRL.

The semiconductor memory device 100 may further include an input/output buffer (not shown), which may receive the control signal CTRL and the address ADDR from outside, and deliver both signals to the control logic 124 and the address decoder 121, respectively. The input/output buffer may deliver the data DATA provided from the outside to the reading and writing circuit 123, and may deliver the data DATA provided from the reading and writing circuit 123.

In an embodiment of the present invention, the semiconductor may be a flash memory device.

FIG. 2 is a view illustrating circuitry of one BLK1 of memory blocks BLK1˜BLKz in FIG. 1.

The memory block BLK1 includes cell strings CS1˜CSm, each of which has a source select transistor SST, source dummy memory cells SM1˜SM3, memory cells M1˜Mn connected in serial, drain dummy memory cells DM1˜DM3 and a drain select transistor DST.

Three dummy memory cells SM1˜SM3 and three dummy memory cells DM1˜DM3 are shown in each of the cell strings for convenience of description. However, the number of the dummy memory cells is not limited to 3.

The memory block BLK1 is connected to the address decoder 121 through a source select line SSL, a first to a third source dummy word lines SDL1˜SDL3, a first to a nth word lines WL1˜WLn, a first to a third drain dummy word lines DDL1˜DDL3 and a drain select line DSL, which encompass RL of FIG. 1. The memory block BLK1 is connected to the reading and writing circuit 123 through a first to an mth bit lines BL1˜BLm.

The source select transistor SST is connected to the source select line SSL, the first to the third source dummy memory cells SM1˜SM3 are connected to the first to the third source dummy word lines SDL1˜SDL3, respectively, the first to the nth memory cells M1˜Mn are connected to the first to the nth word lines WL1˜WLn, respectively, the first to the third drain dummy memory cells DM1˜DM3 are connected to the first to the third drain dummy word lines DDL1˜DDL3, respectively, and finally the drain select transistor DST is connected to the drain select line DSL.

A common source line SL is connected to sources of the source select transistor SST in each of the cell strings CS1˜CSm, and the drain of the drain select transistor DST in each of the cell strings

CS1˜CSm is connected to corresponding bit lines BL1˜BLm.

FIG. 3 is a view illustrating one CS1 of cell strings CS1˜CSm in FIG. 2. FIG. 3 shows only the source select transistor SST, the first to the third source dummy memory cells SM1˜SM3 and a first memory cell M1 for convenience of description.

The memory cell M1 includes a control gate and a floating gate. It is well-known that the dummy memory cell has the same constitution as the memory cell M1, so each source dummy memory cell SDL1˜SDL3 has a control gate and a floating gate. The source select transistor SST includes a contact 20 to electrically connect a control gate to a floating gate.

In the erase operation, the erase voltage Vers having a high voltage level is applied to a bulk area 10. To demonstrate, 0V is provided to a word line WL1, the common source line SL and the source select line SSL are floating. And the voltages applied to the common source line SL and the source select line SSL increase as the erase voltage Vers increases.

It is assumed that 0V is applied to the first to the third source dummy word lines SDL1˜SDL3 as shown in FIG. 3. Voltages of the first to the third source dummy word lines SDL1˜SDL3 maintain 0V, but a voltage of the source select line SSL increases due to the increasing erase voltage Vers applied to the bulk area 10. Accordingly, coupling capacitance C is generated between the source select transistor SST and the first to the third source dummy memory cells SM1˜SM3. When this occurs, an insulating layer between the source select transistor SST and the first to the third source dummy memory cells SM1˜SM3, and especially SM1, are deteriorated. The deterioration increases as the difference between a voltage applied to the first to the third source dummy word lines SDL1˜SDL3 and a voltage provided to the source select line SSL increases. The deterioration also increases as space between memory cells in the memory cell array (100 in FIG. 1) shrinks.

Similarly, an insulating layer between the drain select transistor (DST in FIG. 2) and the first to the third drain dummy memory cell DM1˜DM3 is deteriorated when the erase operation is repetitively performed.

FIG. 4 is a table illustrating voltages applied to row lines RL according to an embodiment of the present invention.

Referring to FIG. 2 and FIG. 4, the word lines voltage Vw1, e.g. ground voltage, is applied to the word lines WL1˜WLn. Threshold voltages of the memory cells M1˜Mn reduce based on the difference between the erase voltage Vers of the bulk area (10 in FIG. 3) and the word line voltage Vw1, thereby erasing data in the memory cells M1˜Mn.

The source select line SSL and the drain select line DSL are floated.

In an embodiment of the present invention, the smaller the space between each of the dummy memory cells SM1˜SM3 or DM1˜DM3 and corresponding select transistor SST or DST, the higher the voltage when applied to corresponding dummy memory cell.

The first source dummy word line SDL1 is adjacent to the source select line SSL, and in an embodiment of the present invention, both have the same voltage. As shown in FIG. 4, the first source dummy word line SDL1 is floating like the source select line SSL. Accordingly, a voltage of the first source dummy word line SDL1 increases to match the voltage of the source select line SSL.

A first dummy word line voltage Vdm1 is applied to a second source dummy word line SDL2. The first dummy word line voltage Vdm1 is less than of the voltage applied to the first source dummy word line SDL1.

A second dummy word line voltage Vdm2 is applied to the third source dummy word line SDL3. The second dummy word line voltage Vdm2 is less than the first dummy word line voltage Vdm1, and in an embodiment of the present invention, the second dummy word line voltage Vdm2 may be greater than or equal to the word line voltage Vw1.

The first to the third drain dummy word lines DDL1˜DDL3 may be controlled similar to how the first to the third source dummy word lines SDL1˜SDL3 may be controlled. In an embodiment of the present invention, the first drain dummy word line DDL1, which may be floating, may have the same voltage as the drain select line DSL. A first dummy word line voltage Vdm1 less than the first drain dummy word line DDL1 may be applied to a second drain dummy word line DDL2, and a second dummy word line voltage Vdm2 less than the first dummy word line voltage Vdm1 may be applied to the third drain dummy word line DDL3.

FIG. 5 is a timing diagram illustrating voltages of row lines RL according to the table in FIG. 4.

Referring to FIG. 2 and FIG. 5, the erase voltage Vers is applied to the bulk area (10 in FIG. 3) at a first time t1. The erase voltage Vers increases to reach a first voltage V1, e.g. 20V.

Since the source select line SSL and the drain select line DSL are floating, voltages of the select lines SSL and DSL increase up to a second voltage V2 when the erase voltage Vers increases. The second voltage V2 is less than the first voltage V1.

Since the first source dummy word line SDL1 is floating, a voltage of the first source dummy word line SDL1 increases up to the second voltage V2 when the erase voltage Vers increases.

The first dummy word line voltage Vdm1 is applied to the second source dummy word line SDL2 at the first time t1. The first dummy word line voltage

Vdm1 increases to reach a third voltage V3 which is less than the second voltage V2.

The second dummy word line voltage Vdm2 is applied to the third source dummy word line SDL3 at a time t2. The second dummy word line voltage Vdm2 may maintain for example a ground voltage, but in an embodiment of the present invention, the second dummy word line voltage Vdm2 may increase to reach a voltage less than the third voltage V3.

The smaller the space between each dummy memory cell SM1˜SM3 connected to the source dummy word lines SDL1˜SDL3 and the source select transistor SST, the higher the voltage applied to corresponding source dummy word line SDL1˜SDL3.

The word line voltage Vw1 may maintain for example a ground voltage. Threshold voltages of the memory cells M1˜Mn may decrease due to a difference of the erase voltage Vers and the word line voltage Vw1.

The first to the third dummy word lines DDL1˜DDL3 are controlled similar to how the first to the third source dummy word lines SDL1˜SDL3 are controlled.

Voltages of the source select line SSL, the drain select line DSL and the first dummy word lines SDL1 and DDL1 having floating state all decrease as the erase voltage Vers decreases at a second time t2.

The second dummy word lines SDL2 and DDL2 are discharged so that the first dummy word line voltage Vdm1 reduces at the second time t2. The second dummy word line voltage Vdm2 may maintain for example the ground voltage.

In an embodiment of the present invention, a higher voltage level is applied to corresponding dummy memory cell SM1˜SM3 and DM1˜DM3 as space between each of the dummy memory cells SM1˜SM3 and DM1˜DM3 and corresponding select transistor SST or DST decreases. Accordingly, the coupling capacitance between the select transistor SST or DST and the dummy memory cells SM1˜SM3 or DM1˜DM3 decreases, thereby deceasing deterioration of the memory cell (110 in FIG. 1) for higher reliability.

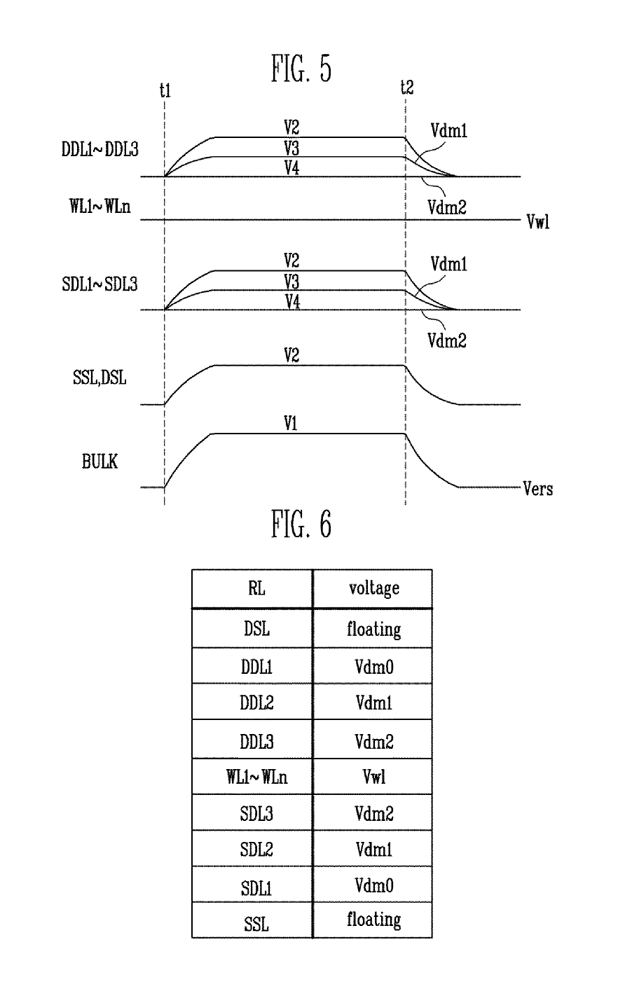

FIG. 6 is a table illustrating voltages applied to row lines RL according to an embodiment of the present invention.

The row lines RL are controlled with a similar control method as in FIG. 5 except that a 0th dummy word line voltage Vdm0 is applied to the first dummy word lines SDL1 and DDL1.

The 0th dummy word line voltage Vdm0 is greater than the first dummy word line voltage Vdm1, which in turn is greater than the second dummy word line voltage Vdm2 as described in FIG. 4 and FIG. 5.

The 0th dummy word line voltage Vdm0 may have the same voltage level as that of the floating source select line SSL and the floating drain select line DSL.

It is to be understood that the present embodiment may have the same effect as the embodiments referred in FIG. 4 and FIG. 5.

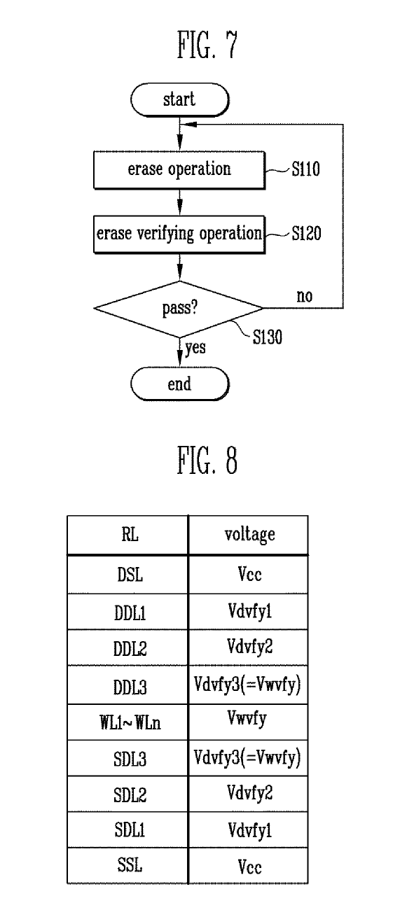

FIG. 7 is a flowchart illustrating a method of erasing the semiconductor memory device in FIG. 1.

Referring to FIG. 1, FIG. 2 and FIG. 7, an erase operation is performed in step S110. The peripheral circuit 120 performs the erase operation by biasing the row lines RL of a selected memory block as described in FIG. 4 to FIG. 6.

In step S120, an erase verifying operation is performed. The peripheral circuit 120 reads threshold voltages of memory cells in the selected memory block, and detects whether or not the threshold voltages of the memory cells reach desired voltages.

Particularly, the bit lines BL1˜BLn are precharged. Subsequently, a verifying voltage is applied to the word lines WL1˜WLn under the condition that the source select transistor SST, the drain select transistor DST and the dummy memory cells SDL1˜SDL3 and DDL1˜DDL3 are turned on. Voltages of the bit lines BL1˜BLn vary depending on turn-on/off of the memory cells M1˜Mn. For example, in case that at least one of the memory cells M1˜Mn is turned off, the voltages of the bit lines BL1˜BLn remain unchanged. The threshold voltages of the memory cells in the selected memory block are checked to see if the desired voltage is reached by sensing the voltages of the bit lines BL1˜BLn.

In step S130, the step S110 is performed again depending on whether or not the threshold voltages of the memory cells in the selected memory block met its desired voltage.

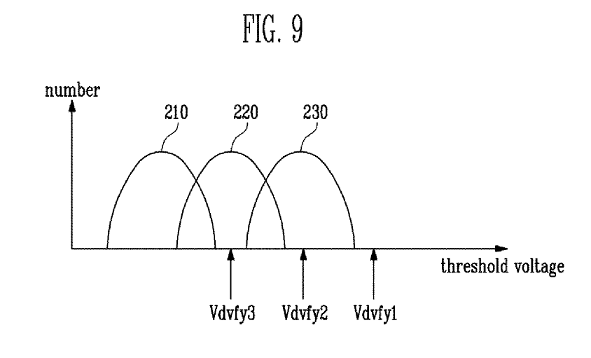

FIG. 8 is a table illustrating voltages applied to the row lines RL in an erase verifying operation.

Referring to FIG. 2 and FIG. 8, a supply voltage Vcc is applied to the source select line SSL and the drain select line DSL, thereby turning on the source select transistor SST and the drain select transistor DST. A word line verifying voltage Vwvfy, e.g. 0V-2V, is applied to the word lines WL1˜WLn.

A first to a third dummy verifying voltages Vdvfy1˜Vdvfy3 are applied to the first to the third source dummy word lines SDL1˜SDL3, respectively. The first dummy verifying voltage Vdvfy1 is greater than the second dummy verifying voltage Vdvfy2, which in turn is greater than the third dummy verifying voltage Vdvfy3, which in turn may have the same level as the word line verifying voltage Vwvfy.

The first to the third dummy verifying voltages Vdvfy1˜Vdvfy3 are applied to the first to the third drain dummy word lines DDL1˜DDL3, respectively.

In an embodiment of the present invention, in the erase verifying operation following the erase operation as described in FIG. 4 to FIG. 6, a verifying voltage having a higher voltage level is applied to corresponding dummy memory cell SM1˜SM3 or DM1˜DM3 as space between the dummy memory cell SM1˜SM3 or DM1˜DM3 and the select transistor SST or DST decreases. Accordingly, the dummy memory cells SM1˜SM3 or DM1˜DM3 may be normally turned on. This will be described in detail with reference to accompanying drawing FIG. 9.

FIG. 9 is a view illustrating threshold voltage distribution of memory cells and dummy memory cells after the erase operation is performed.

Referring to FIG. 2 and FIG. 9, memory cells have first threshold voltage distribution 210. If the second dummy word line voltage Vdm2 applied to the third dummy word lines SDL3 and DDL3 in the erase operation has the same voltage level as the voltage applied to the word lines WL1˜WLn, dummy memory cells connected to the third dummy word lines SDL3 and DDL3 have the first threshold voltage distribution 210.

In the erase operation, the first dummy word line voltage Vdm1, which is greater than the second dummy word line voltage Vdm2 is applied to the second dummy word lines SDL2 and DDL2. Memory cells connected to the second dummy word lines SDL2 and DDL2 have a second threshold voltage distribution 220, which has a higher peak than that of the first threshold voltage distribution 210.

In the erase operation, the first dummy lines SDL1 and DDL1 are floated. The 0th dummy word line voltage Vdm0, which is greater than the first dummy word line voltage Vdm1, is applied to the first dummy word lines SDL1 and DDL1. Accordingly, dummy memory cells connected to the first dummy word lines SDL1 and DDL1 have a third threshold voltage distribution 230, which has a higher peak than that of the second threshold voltage distribution 220.

If the same dummy verifying voltage, e.g. the third dummy verifying voltage Vdvfy3, is applied to each dummy word lines SDL1˜SDL3 and DDL1˜DDL3, dummy memory cells connected to the third dummy word lines SDL3 and DDL3 would have threshold voltages less than the third dummy verifying voltage Vdvfy3. The dummy memory cells connected to the third dummy word lines SDL3, DDL3 would be turned on normally.

Some dummy memory cells connected to the second dummy word lines SDL2 and DDL2 have a threshold voltage greater than the third dummy verifying voltage Vdvfy3, and thus the dummy memory cells are not turned on. Similarly, dummy memory cells connected to the first dummy word lines SDL1 and DDL1 have a threshold voltage greater than the third dummy verifying voltage Vdvfy3, and thus the dummy memory cells are not turned on.

In an embodiment of the present invention, the third dummy verifying voltage Vdvfy3 greater than the first threshold voltages distribution 210 is applied to the third dummy word lines SDL3 and DDL3, the second dummy verifying voltage Vdvfy2 greater than the second threshold voltage distribution is provided to the second dummy word lines SDL2 and DDL2, and the first dummy verifying voltage Vdvfy1 greater than the third threshold voltage distribution is applied to the first dummy word lines SDL1 and DDL1. Since the dummy memory cells of different dummy word lines have different threshold voltage distributions, the dummy verifying voltage having higher voltage level is applied to corresponding dummy memory cells

SM1˜SM3 or DM1˜DM3 as space between the dummy memory cell SM1˜SM3 or DM1˜DM3 and the select transistor SST or DST is reduced. Accordingly, the dummy memory cells connected to the first dummy word lines SDL1 and DDL1, the dummy memory cells connected to the second dummy word lines SDL2 and DDL2, and the dummy memory cells connected to the third dummy word lines SDL3 and DDL3 are normally turned on.

In an embodiment of the present invention, a higher voltage level is provided to corresponding dummy memory cells as space between the dummy memory cell and the select transistor decreases in the erase operation. Accordingly, deterioration of the insulating layer between the select transistor and the dummy memory cells is prevented.

In an embodiment of the present invention, a higher dummy verifying voltage level is applied to corresponding dummy memory cell as space between the dummy memory cell and the select transistor decreases in the erase verifying operation. Accordingly, the dummy memory cells may be normally turned on in the erase verifying operation.

Although embodiments have been described with reference to a number of illustrative embodiments thereof, it should be understood that numerous other modifications and embodiments can be devised by those skilled in the art that will fall within the spirit and scope of the principles of this disclosure.

What is claimed is:

1. A semiconductor memory device comprising:
a select transistor;
memory cells connected in serial; and
dummy memory cells disposed between the select transistor and the memory cells,
wherein a higher voltage is applied to a corresponding dummy memory cell as space between the corresponding dummy memory cell and the select transistor is reduced in an erase operation.

2. The semiconductor memory device of claim 1, wherein a voltage provided to a dummy memory cell adjacent to the select transistor is the same voltage applied to a select line connected to the select transistor.

3. The semiconductor memory device of claim 1, wherein a select line connected to the select transistor and a dummy word line connected to a dummy memory cell adjacent to the select transistor are floating.

4. The semiconductor memory device of claim 1, wherein a voltage applied to a dummy memory cell adjacent to the memory cells is greater than or equal to the voltage applied to the memory cells.

5. The semiconductor memory device of claim 1, wherein in an erase verifying operation after the erase operation is performed, a higher dummy verifying voltage is applied to the corresponding dummy memory cell as space between the corresponding dummy memory cell and the select transistor is decreased.

6. The semiconductor memory device of claim 5, wherein a dummy verifying voltage applied to a dummy memory cell adjacent to the memory cells is greater than or equal to a verifying voltage provided to the memory cells in the erase verifying operation.

7. The semiconductor memory device of claim 1, wherein the select transistor is a drain select transistor disposed between a bit line and the dummy memory cells.

8. The semiconductor memory device of claim 1, wherein the select transistor is a source select transistor disposed between a common source line and the dummy memory cells.

9. A semiconductor memory device comprising:
a memory cell array having a select transistor, memory cells connected in serial, and dummy memory cells disposed between the select transistor and the memory cells; and
a peripheral circuit configured to apply a high level voltage to a corresponding dummy memory cell as space between the corresponding dummy memory cell and the select transistor is reduced in an erase operation.

10. The semiconductor memory device of claim 9, wherein the peripheral circuit is configured to have both a floating select line connected to the select transistor and a floating dummy word line connected to a dummy memory cell adjacent to the select transistor.

11. The semiconductor memory device of claim 9, wherein the peripheral circuit is configured to apply a higher level dummy verifying voltage to the corresponding dummy memory cell as space between the corresponding dummy memory cell and the select transistor is reduced in an erase verifying operation following the erase operation.

12. A method of operating a semiconductor memory device, the method comprising:
floating a select line connected to a select transistor in an erase operation; and
applying a higher level voltage to each dummy memory cell disposed between the select transistor and memory cells as space between a corresponding dummy memory cell and the select transistor is reduced when the select line is floating.

13. The method of claim 12, wherein a voltage applied to a dummy memory cell adjacent to the select transistor has the same voltage level as a voltage applied to the select line.

14. The method of claim 12, wherein a dummy word line connected to a dummy memory cell adjacent to the select transistor is floating.

15. The method of claim 12, further comprising:
applying a high level dummy word line voltage to the each dummy memory cell as space between the corresponding dummy memory cell and the select transistor is reduced in an erase verifying operation following the erase operation.
